(19) United States
(12) Patent Application Publication
(10) Pub. No.: US 2014/0184195 A1
(43) Pub. Date: Jul. 3, 2014

(54) POWER QUALITY MEASURING DEVICE USED IN DISTRIBUTION LINE FOR INTEGRATED VOLTAGE AND VAR CONTROL

(71) Applicants: Tae-Soo CHANG, Seoul (KR); Jong-Tae SHIM, Yongin-si (KR); Yang-Sup JEONG, Sugimoto (KR); Sang-Soo JEON, Seoul (KR)

(72) Inventors: Tae-Soo CHANG, Seoul (KR); Jong-Tae SHIM, Yongin-si (KR); Yang-Sup JEONG, Sugimoto (KR); Sang-Soo JEON, Seoul (KR)

(73) Assignees: IUS TECHNOLOGIES, Alpharetta, GA (US); VITZROSYS CO., LTD., Seoul (KR)

(21) Appl. No.: 13/900,036

(22) Filed: May 22, 2013

(30) Foreign Application Priority Data
Dec. 27, 2012 (KR) 10-2012-0154662

(51) Int. Cl. G01R 19/00

(52) U.S. Cl. CPC G01R 19/00
USPC 324/76.11

(57) ABSTRACT

A power quality measuring and controlling device used in a distribution line includes: a current-voltage sensor part converting a first voltage received through the distribution line into a second voltage, converting a first current into a second current, and signal-processing the converted second voltage and the converted second current and transmitting them by radio communications; and a power quality measuring part receiving the second voltage and the second current from the current-voltage sensor part by radio communications, comparing measured values of the second voltage and the second current with reference measured values, and transmitting only measured data belonging to the reference measured values to the centralized system located in a remote place by radio communications.

### CROSS REFERENCES

This application claims the benefit of Korean Patent Application No. 10-2012-0154662, filed 27 Dec. 2012, which is hereby incorporated by reference in its entirety into this application.

### BACKGROUND OF THE INVENTION

1. Field of the Invention

The present invention relates to a power quality measuring and controlling device used in a distribution line, and more particularly, to a power quality measuring and controlling device used in a distribution line for integrated voltage-Var control and optimization, which has an unsolicited message function based on multiple radio communications.

2. Background Art

FIG. 1 is a view of a distribution network on-the-spot monitoring system according to a prior art.

Referring to FIG. 1, the distribution network on-the-spot monitoring system according to the prior art includes: a voltage-current converter 10 attached to a power pole; and a power quality measuring device 20 connected with the voltage-current converter 10 by wire, the power quality measuring device 20 analyzing and treating a converted voltage-current input signal and transmitting the input signal to a centralized system by wireless communication.

Such a distribution network on-the-spot monitoring system has several problems in that cable lines costs are increased and it is greatly influenced by external environment elements, such as lightening, thunder stroke, and others because the voltage-current converter 10 and the power quality measuring device 20 are mounted by wire.

### SUMMARY OF THE INVENTION

Accordingly, the present invention has been made to solve the above-mentioned problems occurring in the prior arts, and it is an object of the present invention to provide a power quality measuring and controlling device used in a distribution line, which can measure an effective value of voltage of an electrical grid in real time when electric power transmitted from a transformer is transmitted to the final consumers, such as houses and factories, through a distribution network, and manage electric power of the distribution network to be optimized by effectively transmitting power quality through a radio communication network at the time of blackout of the distribution network or at the time that the distribution network is beyond an effective range of voltage.

To achieve the above objects, the present invention provides a power quality measuring and controlling device used in a distribution line comprising: a current-voltage sensor part converting a first voltage received through the distribution line into a second voltage, converting a first current into a second current, and signal-processing the converted second voltage and the converted second current and transmitting them by radio communications; and a power quality measuring part receiving the second voltage and the second current from the current-voltage sensor part by radio communications, comparing measured values of the second voltage and the second current with reference measured values, and transmitting only measured data belonging to the reference measured values to the centralized system located in a remote place by radio communications.

Moreover, the current-voltage sensor part includes: a current signal converting part receiving the first current from the distribution line and converting the first current into the second current which has a signal changed in a voltage change amount of a predetermined ratio; a voltage signal converting part receiving the first voltage from the distribution line and converting the first current into the second current which is a low voltage of a predetermined ratio; a main power source part changing the first voltage received from the distribution line into predetermined voltage and wattage using an induced electromotive force to supply a main power source; and a sensor controlling part converting the main power source supplied from the main power source part into an operational power source, signal-processing the second current received from the current signal converting part and the second voltage received from the voltage signal converting part, and transmitting by radio communications.

Furthermore, the sensor controlling part includes: a charging part converting and storing the main power source supplied from the main power source part into the operational power source and supplying the operational power source; a first signal processing part operated by receiving the operational power source from the charging part, the first signal processing part measuring, analyzing and signal-processing the second current received from the current signal converting part and the second voltage received from the voltage signal converting part; and a radio communication transmitting part transmitting the measured and signal-processed second current and the signal-processed second voltage to the power quality measuring part by radio communications.

Additionally, the power quality measuring part includes: a control power supply part for supplying a main power source so as to operate the power quality measuring part; a site manipulation part receiving the main power source from the control power supply part so as for a user to manipulate power quality situations on the site; a data storing part storing measured values, reference measured values, and measured data of the second voltage and the second current transmitted from the current-voltage sensor part; a signal display part displaying the measured values, the reference measured values and the measured data of the second voltage and the second current so that the user can check them and change the predetermined values; a voltage-current input part electrically connected with the signal display part so as for the user to change and set a range of the reference measured values according to surrounding environment; a second signal processing part arithmetically operating the range of the reference measured values changed and set in the voltage-current input part, and deciding whether or not the arithmetically operated reference measured values belong to the set range of the reference measured values; and a central communication transmitting part transmitting only the measured data belonging to the reference measured values set through the voltage-current input part and the second signal processing part by radio communications.

In addition, the central communication transmitting part includes: a local area network processing part converting the measured data belonging to the reference measured values and transmitting the converted data to the centralized system; and a telecommunications processing part transmitting the measured data according to a communication protocol that the centralized system requires.

Moreover, the telecommunications processing part transmits a response to periodic requests according to a communication protocol that the centralized system requires, and previously informs emergent conditions when an event occurs even though there is no response.

As described above, the power quality measuring and controlling device used in the distribution line according to the present invention includes the current-voltage sensor part and the power quality measuring part, and has the following effects.

First, the power quality measuring and controlling device according to the present invention can monitor situations of the distribution line through a voltage-current signal by radio communications without wiring on a telegraph part.

Second, the power quality measuring and controlling device can transmit time and a measured value only when a predetermined situation set by the centralized system from a remote place occurs in the distribution line site, and can usually monitor the situations of the distribution line in real time through a small radio communication data by storing data in real time.

Third, the power quality measuring and controlling device can realize various functions because the radio communication part, the voltage-current signal input part, the data storing part and the user manipulation part are constituted of separate modules and are easily combinable according to users' demands.

Fourth, the power quality measuring and controlling device can set wanted conditions and change programs from a remote place by radio communications.

Fifth, the power quality measuring and controlling device can grasp situations of the distribution line in real time and control voltage and reactive power of the distribution line through the local control part according to the situations of the distribution line.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a view of a distribution network on-the-spot monitoring system according to a prior art;

FIG. 2 is a block diagram of a power quality measuring and controlling device used in a distribution line according to a preferred embodiment of the present invention;

FIG. 3 is a view of the power quality measuring and controlling device used in the distribution line according to the present invention;

FIG. 4 is a connection diagram of a current-voltage sensor part according to the present invention;

FIG. 5 is a perspective view of the current-voltage sensor part; and

FIG. 6 is a connection diagram of a power quality measuring part according to the present invention.

### DETAILED DESCRIPTION OF THE PREFERRED EMBODIMENT

Reference will be now made in detail to the preferred embodiment of the present invention with reference to the attached drawings, and will be illustrated focusing on essential parts necessary to understand operations and actions of the present invention.

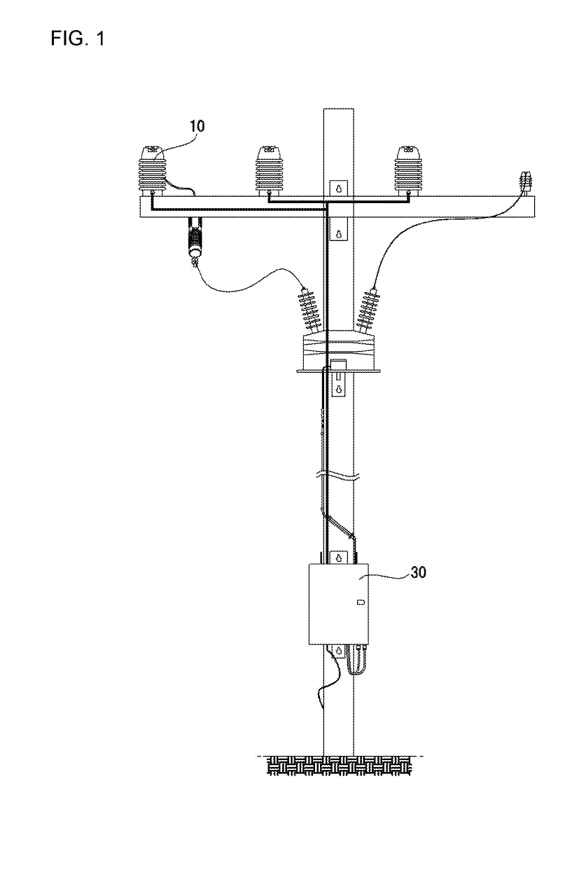

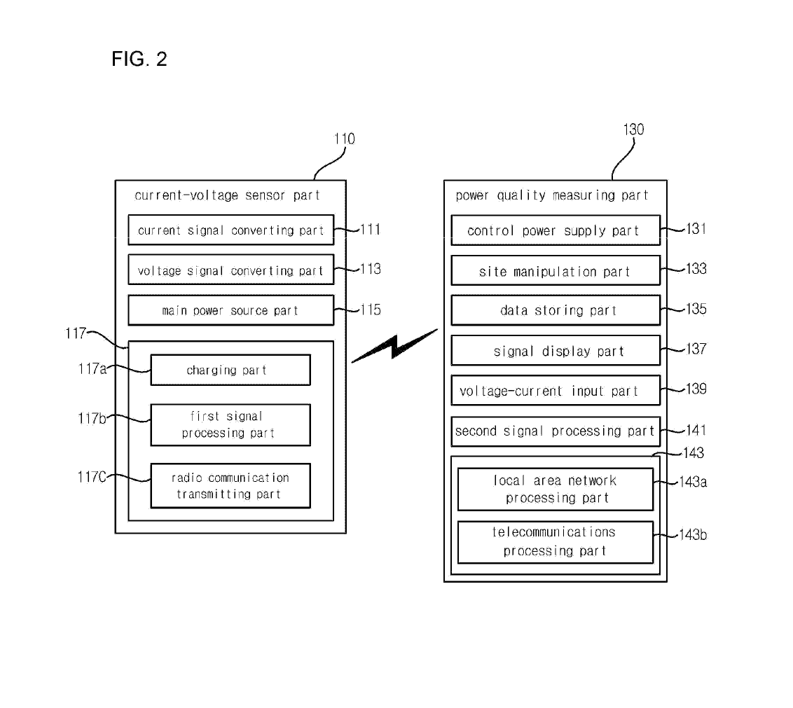

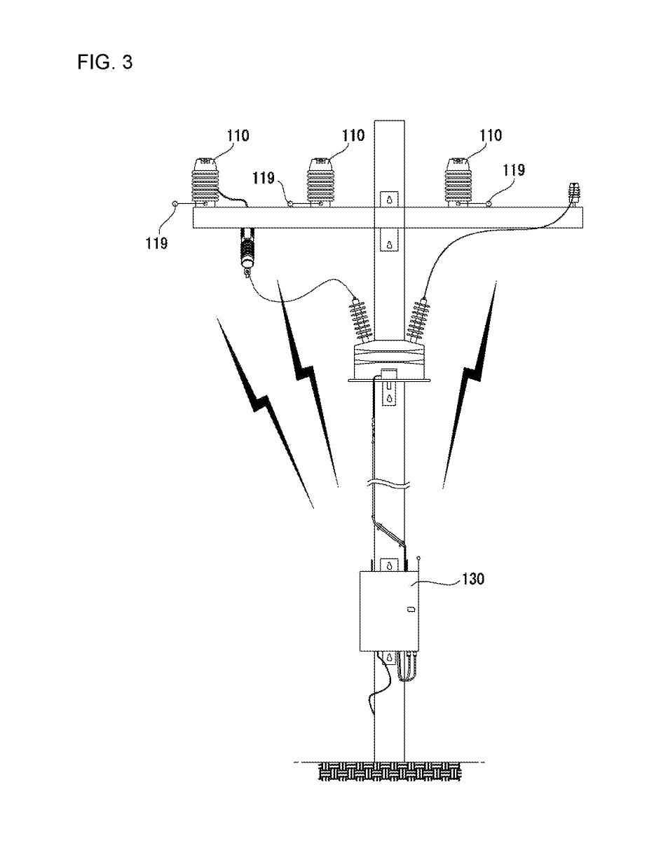

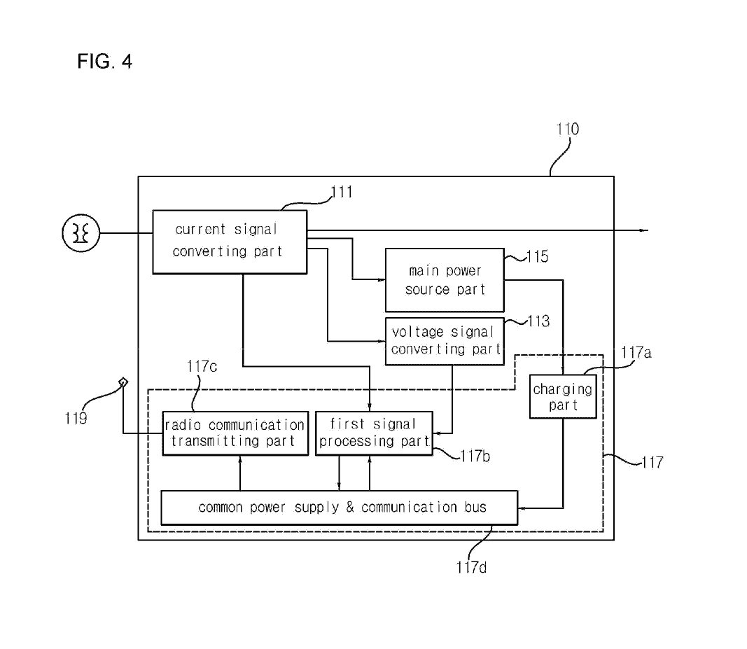

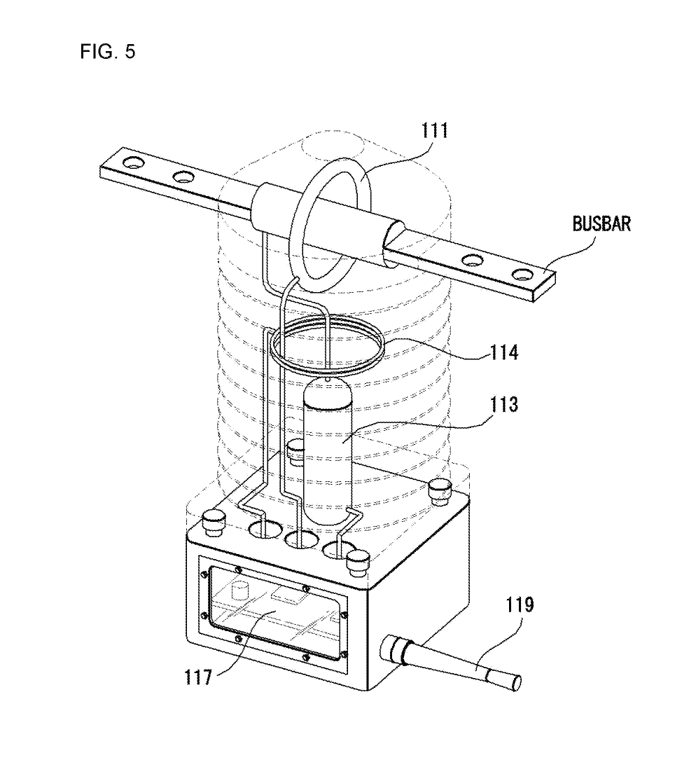

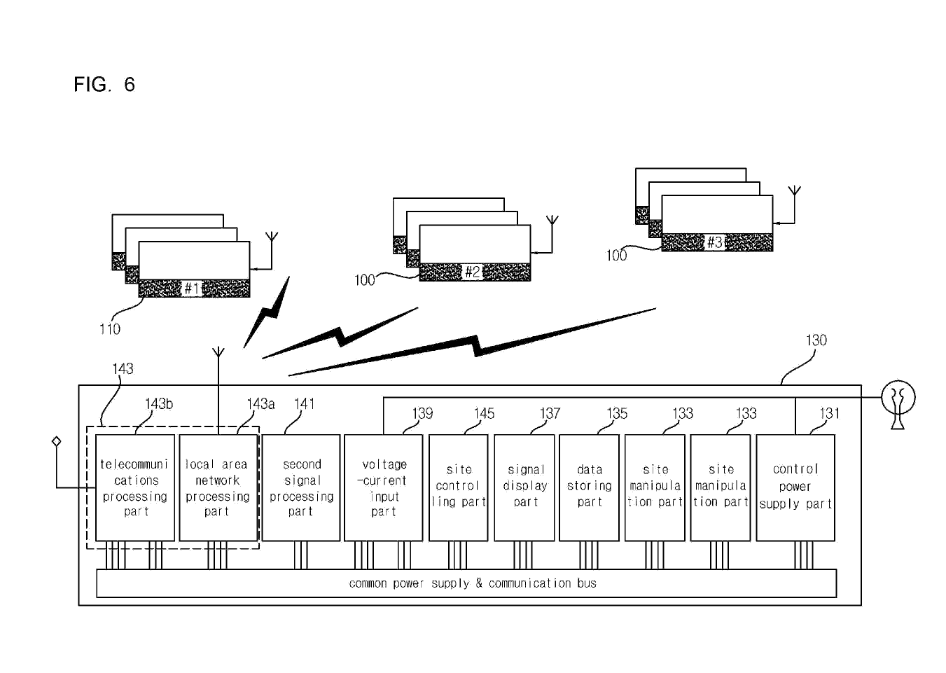

Referring to FIGS. 1 to 6, a power quality measuring and controlling device used in a distribution line according to a preferred embodiment of the present invention includes a current-voltage sensor part 110 and a power quality measuring part 130.

The current-voltage sensor part 110 converts a first voltage received through the distribution line into a second voltage, converts a first current into a second current, and signal-processes the converted second voltage and the converted second current and transmits them by radio communications. Such a current-voltage sensor part 110 includes a current signal converting part 111, a voltage signal converting part 113, a main power source part 115, and a sensor controlling part 117.

The current signal converting part 111 receives the first current from the distribution line and converts the first current into the second current which has a signal changed in a voltage change amount of a predetermined ratio. Such a current signal converting part 111 can convert the first current into the second current by converting the signal into a signal of v(t)=a*di(t)/dt if the first current of the distribution line is i(t).

The voltage signal converting part 113 receives the first voltage from the distribution line and converts the first current into the second current which is a low voltage of a predetermined ratio. Such a voltage signal converting part 113 can convert the first voltage into the second voltage of b*v(t) which is an output voltage of the voltage signal converting part 113 if the first voltage is v(t).

The main power source part 115 changes the first voltage received from the distribution line into predetermined voltage and wattage using an induced electromotive force to supply a main power source.

The sensor controlling part 117 converts the main power source supplied from the main power source part 115 into an operational power source, signal-processes the second current received from the current signal converting part 111 and the second voltage received from the voltage signal converting part 113, and transmits them by radio communications. Such a sensor controlling part 117 includes a charging part 117a, a first signal processing part 117b, and a radio communication transmitting part 117c.

The charging part 117a converts and stores the main power source supplied from the main power source part 115 into operational power source and supplies the operational power source. Such a charging part 117a converts the main power source, which is an AC input power source received through the main power source part 115, into the operational power source, which is a DC power source, and stores the operational power source in a capacitor (not shown) mounted therein. Here, the charging part 117a may supply the operational power source to the sensor controlling part 117, which may be called a “PCB controller” so as to operate the sensor controlling part 117.

The first signal processing part 117b is operated by receiving the operational power source from the charging part 117a, and measures, analyzes and signal-processes the second current received from the current signal converting part 111 and the second voltage received from the voltage signal converting part 113.

The radio communication transmitting part 117c transmits the signal-processed second current and the signal-processed second voltage to the power quality measuring part 130 by radio communications. Here, the radio communication transmitting part 117c may transmit the signal-processed second current and the signal-processed second voltage to the power quality measuring part 130 by radio communications if it is decided that it is necessary to transmit the second current and the second voltage signal-processed in the first signal processing part 117b.

Moreover, the second current and the second voltage may be transmitted between the first signal processing part 117b and the radio communication transmitting part 117c via an internal communication bus type. That is, the first signal processing part 117b and the radio communication transmitting part 117c may be interfaced via the internal communication bus type.

The power quality measuring part 130 receives the second voltage and the second current from the current-voltage sensor part 110 by radio communications, compares measured values of the second voltage and the second current with reference measured values, and transmits only measured data belonging to the reference measured values to the centralized system by radio communications. Such a power quality measuring part 130 includes a control power supply part 131, a site manipulation part 133, a data storing part 135, a signal display part 137, a voltage-current input part 139, a second signal processing part 141, and a central communication transmitting part 143.

The control power supply part 131 supplies a main power source for operating the power quality measuring part 130. Such a control power supply part 131 is a power supply unit and may convert an AC power source into a DC power source in order to supply the main power source for operating the power quality measuring part 130.

The site manipulation part 133 receives the main power source from the control power supply part 131 and allows a user to manipulate power quality situations on the site. At least one of the site manipulation parts 133 is arranged, and the user can set the power quality situations using buttons and the signal display part (LCD) 137 which will be described later.

The data storing part 135 stores the measured values, the reference measured values, and measured data of the second voltage and the second current transmitted from the current-voltage sensor part 110. Such a data storing part 135 stores the measured values, the reference measured values and the measured data of the second voltage and the second current in real time and can store them separately even though a special event occurs. Here, the data storing part 135 may be formed in a memory card type, a SD card type, or one of other types.

Furthermore, the data storing part 135 may be used for the purpose of firmware update if the user wants to use it as another device through firmware upgrade.

The signal display part 137 displays the measured values, the reference measured values and the measured data of the second voltage and the second current so that the user can check them and change the predetermined values.

The voltage-current input part 139 is electrically connected with the signal display part 137 so as for the user to change and set a range of the reference measured values according to surrounding environment. Such a voltage-current input part 139 may be constituted of separate modules in such a way as to be selected according to kinds and the number and the ranges of voltages and currents. Additionally, the voltage-current input part 139 can change the range of the reference measured values and processes it through A/D conversion sampling by a set cycle.

The second signal processing part 141 arithmetically operates the range of the reference measured values changed and set in the voltage-current input part 139, and decides whether or not the arithmetically operated reference measured values belong to the set range of the reference measured values. Such a second signal processing part 141 receives the A/D conversion sampling data from the voltage-current input part 139 via internal communications and arithmetically operates and processes the data by RMS, phase angle, power factor, harmonic components, and so on to be measured.

Moreover, the second signal processing part 141 decides whether or not the arithmetically operated results belong to the set range of the reference measured values.

The central communication transmitting part 143 transmits only the measured data belonging to the reference measured values set through the voltage-current input part 139 and the second signal processing part 141 by radio communications. Such a central communication transmitting part 143 may include a local area network processing part 143a and a telecommunications processing part 143b.

The local area network processing part 143a converts the measured data belonging to the reference measured values and transmits the converted data to the centralized system.

The telecommunications processing part 143b transmits the measured data according to a communication protocol that the centralized system requires. Such a telecommunications processing part 143b transmits a response to periodic requests according to a communication protocol that the centralized system requires, and can previously inform emergent conditions when an event occurs even though there is no response.

Furthermore, as shown in the drawing, the power quality measuring part 130 can use the sub-components through a common power supply bus and interchange data among the sub-components except the control power supply part 131 through a common communication bus.

Additionally, the power quality measuring part 130 can separate the control power supply part 131, the site manipulation part 133, the data storing part 135, the signal display part 137, the voltage-current input part 139, the second signal processing part 141, and the central communication transmitting part 143 from one another by separate modules. Therefore, the power quality measuring and controlling device according to the present invention can have various functions through combination of the separate modules according to the user's requests.

As described above, the power quality measuring and controlling device according to the present invention can reduce cable line installation costs and minimize influences by external environment elements, such as lightening, thunder stroke, and others, because it is constructed via radio communications.

Moreover, the power quality measuring and controlling device according to the present invention which is constructed via radio communications can remarkably reduce a network traffic amount because it can transmit data only when there occurs a special event or accident in the distribution line site.

While the present invention has been particularly shown and described with reference to the preferable embodiment thereof, it will be understood by those of ordinary skill in the art that the present invention is not limited to the above embodiment and various changes may be made therein without departing from the technical idea of the present invention. Therefore, it would be understood that the technical and protective scope of the present invention shall be defined by the technical idea as defined by the following claims and equivalents of the claims.

What is claimed is:

1. A power quality measuring and controlling device used in a distribution line comprising:
a current-voltage sensor part converting a first voltage received through the distribution line into a second voltage, converting a first current into a second current, and signal-processing the converted second voltage and the converted second current and transmitting them by radio communications; and
a power quality measuring part receiving the second voltage and the second current from the current-voltage sensor part by radio communications, comparing measured values of the second voltage and the second current with reference measured values, and transmitting only measured data belonging to the reference measured values to the centralized system located in a remote place by radio communications.

2. The power quality measuring and controlling device according to claim 1, wherein the current-voltage sensor part comprises:
a current signal converting part receiving the first current from the distribution line and converting the first current into the second current which has a signal changed in a voltage change amount of a predetermined ratio;
a voltage signal converting part receiving the first voltage from the distribution line and converting the first current into the second current which is a low voltage of a predetermined ratio;
a main power source part changing the first voltage received from the distribution line into predetermined voltage and wattage using an induced electromotive force to supply a main power source; and
a sensor controlling part converting the main power source supplied from the main power source part into an operational power source, signal-processing the second current received from the current signal converting part and the second voltage received from the voltage signal converting part, and transmitting by radio communications.

3. The power quality measuring and controlling device according to claim 2, wherein the sensor controlling part comprises:
a charging part converting and storing the main power source supplied from the main power source part into the operational power source and supplying the operational power source;
a first signal processing part operated by receiving the operational power source from the charging part, the first signal processing part measuring, analyzing and signal-processing the second current received from the current signal converting part and the second voltage received from the voltage signal converting part; and
a radio communication transmitting part transmitting the measured and signal-processed second current and the signal-processed second voltage to the power quality measuring part by radio communications.

4. The power quality measuring and controlling device according to claim 3, wherein the power quality measuring part comprises:
a control power supply part for supplying a main power source so as to operate the power quality measuring part;
a site manipulation part receiving the main power source from the control power supply part so as for a user to manipulate power quality situations on the site;
a data storing part storing measured values, reference measured values, and measured data of the second voltage and the second current transmitted from the current-voltage sensor part;
a signal display part displaying the measured values, the reference measured values and the measured data of the second voltage and the second current so that the user can check them and change the predetermined values;
a voltage-current input part electrically connected with the signal display part so as for the user to change and set a range of the reference measured values according to surrounding environment;
a second signal processing part arithmetically operating the range of the reference measured values changed and set in the voltage-current input part, and deciding whether or not the arithmetically operated reference measured values belong to the set range of the reference measured values; and
a central communication transmitting part transmitting only the measured data belonging to the reference measured values set through the voltage-current input part and the second signal processing part by radio communications.

5. The power quality measuring and controlling device according to claim 4, wherein the central communication transmitting part comprises:
a local area network processing part converting the measured data belonging to the reference measured values and transmitting the converted data to the centralized system; and
a telecommunications processing part transmitting the measured data according to a communication protocol that the centralized system requires.

6. The power quality measuring and controlling device according to claim 5, wherein the telecommunications processing part transmits a response to periodic requests according to a communication protocol that the centralized system requires, and previously informs emergent conditions when an event occurs even though there is no response.
